(19) United States
(12) Patent Application Publication
(10) Pub. No.: US 2011/0316647 A1
(43) Pub. Date: Dec. 29, 2011

(54) ELASTIC WAVE BRANCHING FILTER

(75) Inventors: Minefumi OUCHI, Nagaokakyo-shi (JP); Tomohisa KOMURA, Nagaokakyo-shi (JP)

(73) Assignee: MURATA MANUFACTURING CO., LTD., Nagaokakyo-shi (JP)

(21) Appl. No.: 13/164,789

(22) Filed: Jun. 21, 2011

(30) Foreign Application Priority Data
Jun. 25, 2010 (JP) 2010-145222

(51) Int. Cl. H03H 9/70; H03H 9/72

(52) U.S. Cl. 333/133; 333/195; 333/189

(57) ABSTRACT

A reception filter includes a first and second longitudinally coupled resonator-type surface acoustic wave filter portions and a surface acoustic wave resonator. The first and second longitudinally coupled resonator-type surface acoustic wave filter portions each include at least three IDT electrodes. The surface acoustic wave resonator includes one IDT electrode connected to at least one of the at least three IDT electrodes. The reception filter is arranged such that a ratio of a capacitance of the surface acoustic wave resonator to a capacitance of each of the at least one of the at least three IDT electrodes included in the longitudinally coupled resonator-type surface acoustic wave filter portion, the at least one of the at least three IDT electrodes being electrically connected to the one IDT electrode of the surface acoustic wave resonator, is in the range of about 1.9 to about 2.5.

### BACKGROUND OF THE INVENTION

1. Field of the Invention

The present invention relates to an elastic wave branching filter using elastic waves, such as surface acoustic waves.

2. Description of the Related Art

A cellular phone that supports code division multiple access (CDMA), such as a universal mobile telecommunications system (UMTS), transmits and receives signals simultaneously. Thus, since it is necessary to separate a transmission signal from a reception signal, a radio frequency (RF) circuit of such a cellular phone includes a duplexer. A duplexer is a branching filter that includes a transmission filter, a reception filter, and a matching circuit. As the transmission filter and the reception filter, surface acoustic wave filters have been widely used.

To produce small and sophisticated cellular phones, many attempts have been made to reduce the size of RF circuits. For example, as described in International Publication No. WO2007/116760 A1, a balanced longitudinally coupled resonator-type surface acoustic wave filter arranged to perform a balanced-unbalanced transforming function may be used as a reception filter. When such a surface acoustic wave filter is used as a reception filter, there is no need to additionally provide a balun on an RF circuit. This makes it possible to significantly reduce the size of cellular phones.

In a duplexer described in International Publication No. WO2007/116760 A1, a balanced longitudinally coupled resonator-type surface acoustic wave filter is used as a reception filter, and a ladder-type surface acoustic wave filter is used as a transmission filter. The balanced longitudinally coupled resonator-type surface acoustic wave filter used as the reception filter includes a longitudinally coupled resonator-type surface acoustic wave filter portion and a one-port surface acoustic wave resonator. The one-port surface acoustic wave resonator is electrically connected between the longitudinally coupled resonator-type surface acoustic wave filter portion and an antenna terminal.

In a duplexer, such as that described in International Patent Application Publication No. WO2007/116760 A1, which includes a balanced longitudinally coupled resonator-type surface acoustic wave filter as a reception filter, the inter-modulation distortion (IMD) level may be high.

### SUMMARY OF THE INVENTION

To overcome the problems described above, preferred embodiments of the present invention provide an elastic wave branching filter having excellent filter characteristics and a low inter-modulation distortion level.

An elastic wave branching filter according to a preferred embodiment of the present invention preferably includes an antenna terminal, a reception signal terminal, a transmission signal terminal, a reception filter, and a transmission filter. The reception filter is connected between the antenna terminal and the reception signal terminal. The transmission filter is connected between the antenna terminal and the transmission signal terminal. The reception filter preferably includes a longitudinally coupled resonator-type elastic wave filter portion and an elastic wave resonator. The longitudinally coupled resonator-type elastic wave filter portion is connected between the antenna terminal and the reception signal terminal. The longitudinally coupled resonator-type elastic wave filter portion preferably includes at least three IDT electrodes arranged in an elastic wave propagation direction. The elastic wave resonator is connected between the longitudinally coupled resonator-type elastic wave filter portion and the antenna terminal. The elastic wave resonator preferably includes one IDT electrode connected to at least one of the at least three IDT electrodes included in the longitudinally coupled resonator-type elastic wave filter portion. The reception filter is preferably configured such that the ratio of C1 to C2 (C1/C2) is in the range of, for example, about 1.9 to about 2.5, where C1 is a capacitance of the elastic wave resonator and C2 is a capacitance of each of the at least one of the at least three IDT electrodes included in the longitudinally coupled resonator-type elastic wave filter portion, the at least one of the at least three IDT electrodes being connected to the one IDT electrode of the elastic wave resonator.

In the elastic wave branching filter according to a preferred embodiment of the present invention, the transmission filter may preferably be a ladder-type elastic wave filter, for example. With this configuration, it is possible to improve the electric power handling capability of the transmission filter to which a large electric power is applied.

In the elastic wave branching filter according to another preferred embodiment of the present invention, the reception filter may preferably be a balanced longitudinally coupled resonator-type elastic wave filter arranged to perform a balanced-unbalanced transforming function, for example. When an elastic wave branching filter having this configuration is used, there is no need to provide an additional component having a balanced-unbalanced transforming function, such as a balun, downstream of the elastic wave branching filter. Therefore, for example, it is possible to reduce the size of an RF circuit.

In the elastic wave branching filter according to another preferred embodiment of the present invention, the reception filter may preferably be a surface acoustic wave filter using surface acoustic waves or a boundary acoustic wave filter using boundary acoustic waves, for example.

In various preferred embodiments of the present invention, the reception filter of the elastic wave branching filter preferably includes the longitudinally coupled resonator-type elastic wave filter portion and the elastic wave resonator. The reception filter is configured such that the ratio of C1 to C2 (C1/C2) is preferably in the range of, for example, about 1.9 to about 2.5, where C1 is a capacitance of the elastic wave resonator and C2 is a capacitance of each of at least one of the at least three IDT electrodes of the longitudinally coupled resonator-type elastic wave filter portion, the at least one of the at least three IDT electrodes being connected to the one IDT electrode of the elastic wave resonator. Therefore, it is possible to reduce the inter-modulation distortion level without degrading the filter characteristics of the reception filter.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic circuit diagram of a duplexer which is an elastic wave branching filter according to a preferred embodiment of the present invention.

FIG. 2 is a graph showing a relationship between a capacitance ratio C1/C2 and an inter-modulation distortion level.

FIG. 3 is a schematic diagram illustrating an inter-modulation distortion measurement system.

FIG. 4 is a schematic circuit diagram of a duplexer including an elastic wave branching filter according to a first modification of a preferred embodiment of the present invention.

FIG. 5 is a schematic circuit diagram of a duplexer including an elastic wave branching filter according to a second modification of a preferred embodiment of the present invention.

FIG. 6 is a schematic circuit diagram of a duplexer including an elastic wave branching filter according to a third modification of a preferred embodiment of the present invention.

FIG. 7 is a schematic circuit diagram of a duplexer including an elastic wave branching filter according to a fourth modification of a preferred embodiment of the present invention.

FIG. 8 is a schematic circuit diagram of a duplexer including an elastic wave branching filter according to a fifth modification of a preferred embodiment of the present invention.

FIG. 9 is a schematic circuit diagram of a duplexer including an elastic wave branching filter according to a sixth modification of a preferred embodiment of the present invention.

FIG. 10 is a schematic circuit diagram of a duplexer including an elastic wave branching filter according to a seventh modification of a preferred embodiment of the present invention.

### DETAILED DESCRIPTION OF THE PREFERRED EMBODIMENTS

Preferred embodiments of the present invention will be described below with reference to the drawings.

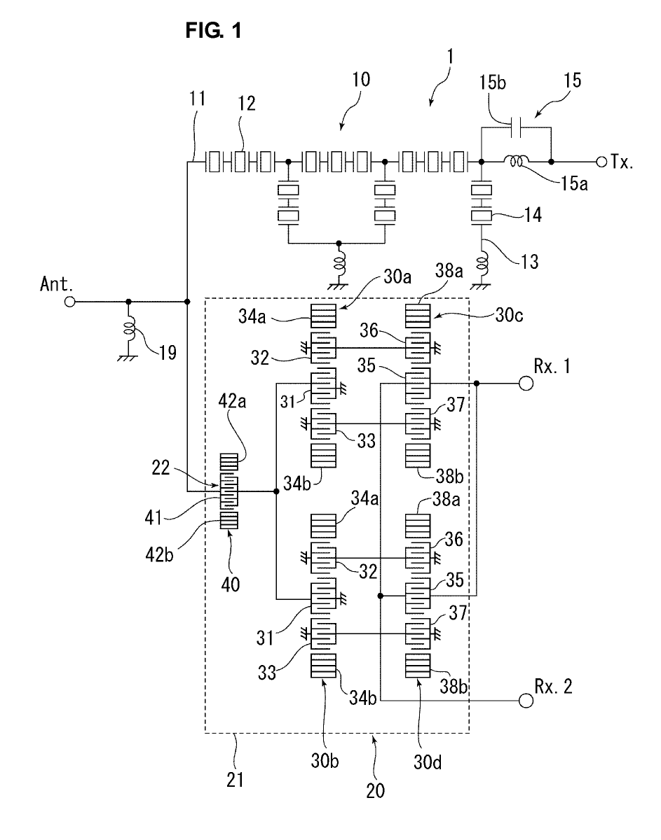

FIG. 1 is a schematic circuit diagram of a duplexer 1 which is an elastic wave branching filter according to a preferred embodiment of the present invention.

Although the present preferred embodiment describes the duplexer 1 illustrated in FIG. 1, an elastic wave branching filter according to preferred embodiments of the present invention is not limited to a duplexer. For example, an elastic wave branching filter according to preferred embodiments of the present invention may be a triplexer.

The duplexer 1 illustrated in FIG. 1 preferably supports UMTS-BAND2. A transmission passband for UMTS-BAND2 is from about 1850 MHz to about 1910 MHz, and a reception passband for UMTS-BAND2is from about 1930 MHz to about 1990 MHz.

The duplexer 1 preferably includes an antenna terminal Ant., a first reception signal terminal Rx. 1, a second reception signal terminal Rx. 2, and a transmission signal terminal Tx. A transmission filter 10 is electrically connected between the antenna terminal Ant. and the transmission signal terminal Tx. In the present preferred embodiment, a ladder-type surface acoustic wave filter is preferably used as the transmission filter 10. The transmission filter 10 includes a series arm 11 electrically connected between the antenna terminal Ant. and the transmission signal terminal Tx. In the series arm 11, a plurality of series arm resonators 12 are electrically connected in series. A plurality of parallel arms 13 are electrically connected between the series arm 11 and the ground potential. Each of the plurality of parallel arms 13 is preferably provided with one or more parallel arm resonators 14. Each of the series arm resonators 12 and the parallel arm resonators 14 is preferably a surface acoustic wave resonator including one interdigital transducer (IDT) electrode and one pair of reflectors arranged on both sides of the IDT electrode in a surface acoustic wave propagation direction. An LC resonance circuit 15 including an inductor 15a and a capacitor 15b is electrically connected between the transmission filter 10 and the transmission signal terminal Tx.

A reception filter 20 is electrically connected between the antenna terminal Ant. and the first and second reception signal terminals Rx. 1 and Rx. 2. A matching circuit is electrically connected between the antenna terminal Ant. and a node between the reception filter 20 and the transmission filter 10. In the present preferred embodiment, an inductor 19 is preferably provided as the matching circuit. The inductor 19 is connected at one end to the antenna terminal Ant. and connected at the other end to the ground potential.

The reception filter 20 is preferably a surface acoustic wave filter that utilizes surface acoustic waves. The reception filter 20 preferably includes a piezoelectric substrate 21 and an electrode 22 provided on the piezoelectric substrate 21. The electrode 22 includes IDT electrodes, reflectors, and wires. The piezoelectric substrate 21 may preferably be formed of, for example, LiNbO₃, LiTaO₃, or quartz. In the present preferred embodiment, a 40±5° Y-cut X-propagation LiTaO₃ substrate will be described as an example of the piezoelectric substrate 21.

Preferably, the electrode 22 may be made of a metal selected from a group of Al, Pt, Au, Ag, Cu, Ni, and Pd, or may be made of an alloy of one or more types of metal selected from the group of Al, Pt, Au, Ag, Cu, Ni, and Pd, for example. The electrode 22 may preferably be a laminated body including a plurality of conductive layers made of the metal or alloy described above. In the present preferred embodiment, the electrode 22 made of Al will be described as an example.

The reception filter 20 is preferably a balanced longitudinally coupled resonator-type surface acoustic wave filter arranged to perform a balanced-unbalanced transforming function. That is, in the reception filter 20, an unbalanced signal is input from the antenna terminal Ant. and a balanced signal is output from the first and second reception signal terminals Rx. 1 and Rx. 2. This means that the first and second reception signal terminals Rx. 1 and Rx. 2 function as first and second balanced signal terminals, respectively. The reception filter 20 preferably has an input impedance of about 50Ω and an output impedance of about 100Ω, for example. This means that the reception filter 20 has an impedance conversion function.

The reception filter 20 preferably includes a first longitudinally coupled resonator-type surface acoustic wave filter portion (“first filter portion”) 30a, a second longitudinally coupled resonator-type surface acoustic wave filter portion (“second filter portion”) 30b, a third longitudinally coupled resonator-type surface acoustic wave filter portion (“third filter portion”) 30c, a fourth longitudinally coupled resonator-type surface acoustic wave filter portion (“fourth filter portion”) 30d, and a surface acoustic wave resonator 40.

The surface acoustic wave resonator 40 is connected at one end to the antenna terminal Ant. and connected at the other end to the first and second filter portions 30a and 30b. That is, the surface acoustic wave resonator 40 is electrically connected between the antenna terminal Ant. and the first and second filter portions 30a and 30b.

The first filter portion 30a includes at least three IDT electrodes arranged in the surface acoustic wave propagation direction. Specifically, in the present preferred embodiment, the first filter portion 30a preferably includes an IDT electrode 31, IDT electrodes 32 and 33 arranged on both sides of the IDT electrode 31 in the surface acoustic wave propagation direction, and reflectors 34a and 34b arranged on both sides in the surface acoustic wave propagation direction of the region in which the IDT electrodes 31 to 33 are arranged. That is, the first filter portion 30a is a three-IDT longitudinally coupled resonator-type surface acoustic wave filter.

The second filter portion 30b preferably has the same or substantially the same configuration as that of the first filter portion 30a. Specifically, the second filter portion 30b preferably includes the IDT electrode 31, the IDT electrodes 32 and 33 arranged on both sides of the IDT electrode 31 in the surface acoustic wave propagation direction, and the reflectors 34a and 34b arranged on both sides in the surface acoustic wave propagation direction of the region in which the IDT electrodes 31 to 33 are arranged. That is, the second filter portion 30b is also a three-IDT longitudinally coupled resonator-type surface acoustic wave filter.

In the present preferred embodiment, the third filter portion 30c is preferably cascade-connected to the first filter portion 30a. The third filter portion 30c is also preferably a three-IDT longitudinally coupled resonator-type surface acoustic wave filter. Specifically, the third filter portion 30c includes an IDT electrode 35, IDT electrodes 36 and 37 arranged on both sides of the IDT electrode 35 in the surface acoustic wave propagation direction, and reflectors 38a and 38b arranged on both sides in the surface acoustic wave propagation direction of the region in which the IDT electrodes 35 to 37 are arranged.

At the same time, the fourth filter portion 30d is preferably cascade-connected to the second filter portion 30b. The fourth filter portion 30d preferably has the same or substantially the same configuration as that of the third filter portion 30c. That is, the fourth filter portion 30d is also a three-IDT longitudinally coupled resonator-type surface acoustic wave filter. Specifically, the fourth filter portion 30d preferably includes the IDT electrode 35, the IDT electrodes 36 and 37 arranged on both sides of the IDT electrode 35 in the surface acoustic wave propagation direction, and the reflectors 38a and 38b arranged on both sides in the surface acoustic wave propagation direction of the region in which the IDT electrodes 35 to 37 are arranged.

That is, in the present preferred embodiment, the first and third filter portions 30a and 30c that are cascade-connected to each other are connected in parallel to the second and fourth filter portions 30b and 30d that are cascade-connected to each other. Therefore, it is possible to reduce ohmic loss caused by electrode finger resistance.

The IDT electrode 31 of the first filter portion 30a is connected at one end through the surface acoustic wave resonator 40 to the antenna terminal Ant. and connected at the other end to the ground potential. That is, the IDT electrode 31 of the first filter portion 30a is an IDT electrode connected to the surface acoustic wave resonator 40.

The IDT electrode 32 of the first filter portion 30a is connected at one end to the ground potential and connected at the other end to the IDT electrode 36 of the third filter portion 30c. The IDT electrode 33 of the first filter portion 30a is connected at one end to the ground potential and connected at the other end to the IDT electrode 37 of the third filter portion 30c.

The IDT electrode 36 of the third filter portion 30c is connected to the ground potential at an end portion opposite to the end connected to the IDT electrode 32 of the first filter portion 30a. Similarly, the IDT electrode 37 of the third filter portion 30c is connected to the ground potential at an end portion opposite to the end connected to the IDT electrode 33 of the first filter portion 30a. The IDT electrode 35 of the third filter portion 30c is connected at one end to the first reception signal terminal Rx. 1 and connected at the other end to the second reception signal terminal Rx. 2.

The IDT electrode 31 of the second filter portion 30b is connected at one end through the surface acoustic wave resonator 40 to the antenna terminal Ant. and connected at the other end to the ground potential. Specifically, the IDT electrode 31 of the second filter portion 30b and the IDT electrode 31 of the first filter portion 30a are connected at one end in common through the surface acoustic wave resonator 40 to the antenna terminal Ant. That is, the IDT electrode 31 of the second filter portion 30b is an IDT electrode connected to the surface acoustic wave resonator 40.

The IDT electrode 32 of the second filter portion 30b is connected at one end to the ground potential, and connected at the other end to the IDT electrode 36 of the fourth filter portion 30d. The IDT electrode 33 of the second filter portion 30b is connected at one end to the ground potential, and connected at the other end to the IDT electrode 37 of the fourth filter portion 30d.

The IDT electrode 36 of the fourth filter portion 30d is connected to the ground potential at an end portion opposite the end connected to the IDT electrode 32 of the second filter portion 30b. Similarly, the IDT electrode 37 of the fourth filter portion 30d is connected to the ground potential at an end portion opposite the end connected to the IDT electrode 33 of the second filter portion 30b. The IDT electrode 35 of the fourth filter portion 30d is connected at one end to the first reception signal terminal Rx. 1 and connected at the other end to the second reception signal terminal Rx. 2. Specifically, the IDT electrode 35 of the fourth filter portion 30d and the IDT electrode 35 of the third filter portion 30c are connected at one end in common to the first reception signal terminal Rx. 1. Similarly, the IDT electrode 35 of the fourth filter portion 30d and the IDT electrode 35 of the third filter portion 30c are connected at the other end in common to the second reception signal terminal Rx. 2.

In the present preferred embodiment, the IDT electrodes of the third and fourth filter portions 30c and 30d are preferably connected at one end to the first reception signal terminal Rx. 1, and connected at the other end to the second reception signal terminal Rx. 2. This makes it possible to output a balanced signal from the first and second reception signal terminals Rx. 1 and Rx. 2.

In the first to fourth filter portions 30a to 30d of the present preferred embodiment, the IDT electrodes preferably include narrow-pitch electrode finger portions at their ends adjacent to each other. A narrow-pitch electrode finger portion is a portion in which a pitch of electrode fingers of an IDT electrode is less than that in the other portions of the same IDT electrode.

In the present preferred embodiment, the surface acoustic wave resonator 40 is electrically connected between the antenna terminal Ant. and the first and second filter portions 30a and 30b. Specifically, the surface acoustic wave resonator 40 is electrically connected between the antenna terminal Ant. and the IDT electrodes 31 of the first and second filter portions 30a and 30b.

By adjusting the impedance of the reception filter 20, the surface acoustic wave resonator 40 preferably matches the phase of the reception filter 20 to that of the transmission filter 10, and allows the reception filter 20 and the transmission filter 10 to be connected in common to the antenna terminal Ant.

The surface acoustic wave resonator 40 is preferably a one-port surface acoustic wave resonator which includes an IDT electrode 41 and reflectors 42a and 42b arranged on both sides of the IDT electrode 41 in the surface acoustic wave propagation direction. The IDT electrode 41 is connected at one end to the antenna terminal Ant. and electrically connected at the other end to the IDT electrodes 31 of the first and second filter portions 30a and 30b. Although the surface acoustic wave resonator 40 of the present preferred embodiment preferably includes the IDT electrode 41 and the reflectors 42a and 42b, preferred embodiments of the present invention are not limited to this configuration. A surface acoustic wave resonator according to a preferred embodiment the present invention may preferably be a one-port surface acoustic wave resonator including one IDT electrode but not including any reflectors.

The surface acoustic wave resonator 40 is preferably configured such that its resonance frequency is within the passband of the reception filter 20 and its anti-resonance frequency is greater than the passband of the reception filter 20. The resonance frequency and anti-resonance frequency of the surface acoustic wave resonator 40 may be in frequency bands different from those described above.

The capacitance of the surface acoustic wave resonator 40 is denoted by C1. In the first and second filter portions 30a and 30b, the capacitance of each of the IDT electrodes 31 connected to the IDT electrode 41 of the surface acoustic wave resonator 40 is denoted by C2. In the present preferred embodiment, the reception filter 20 is preferably configured such that the ratio of the capacitance C1 to the capacitance C2 (C1/C2) is in the range of about 1.9 to about 2.5, for example. Therefore, in the present preferred embodiment, it is possible to reduce the inter-modulation distortion level without degrading the filter characteristics of the reception filter 20. That is, it is possible to achieve both excellent filter characteristics and a low inter-modulation distortion level. This advantage will be described in detail below.

Currently, there are a plurality of communication systems that utilize various frequency bands. Therefore, an antenna of a communication device, such as a cellular phone, receives not only a reception signal but also various types of signals (interfering waves) having frequency bands different from that of the reception signal. A cellular phone that supports CDMA simultaneously transmits and receives signals using a branching filter, such as the duplexer 1 of the present preferred embodiment. Therefore, not only a reception signal but also interfering waves flow into a reception filter included in the branching filter. At the same time, a transmission signal leaking from the transmission side also flows into the reception filter. The interfering waves and the leaking transmission signal that flow into the reception filter may cause inter-modulation and generate a distortion component having a frequency within the passband of the reception filter. This is called inter-modulation distortion. If inter-modulation distortion occurs within the passband of the reception filter, the reception level may deteriorate. To achieve good reception sensitivity of the communication device or to make the communication device less sensitive to interfering waves, it is necessary to reduce the inter-modulation distortion level.

As described above, by adjusting the impedance of the reception filter 20, the surface acoustic wave resonator 40 matches the phase of the reception filter 20 to that of the transmission filter 10, and enables the reception filter 20 and the transmission filter 10 to be connected in common to the antenna terminal Ant.

For a higher degree of freedom in adjusting the impedance of the reception filter 20, it is preferable to increase capacitance of the surface acoustic wave resonator 40. However, an increase in capacitance of the surface acoustic wave resonator 40 produces an increase in the difference between the capacitance C1 of the surface acoustic wave resonator 40 and the capacitance C2 of each of the IDT electrodes 31 of the first and second filter portions 30a and 30b. This leads to a large difference between the impedance of the surface acoustic wave resonator 40 and that of each IDT electrode 31. Therefore, it is difficult to achieve good impedance matching between the surface acoustic wave resonator 40 and the IDT electrode 31 and, as a result, the inter-modulation distortion level is increased.

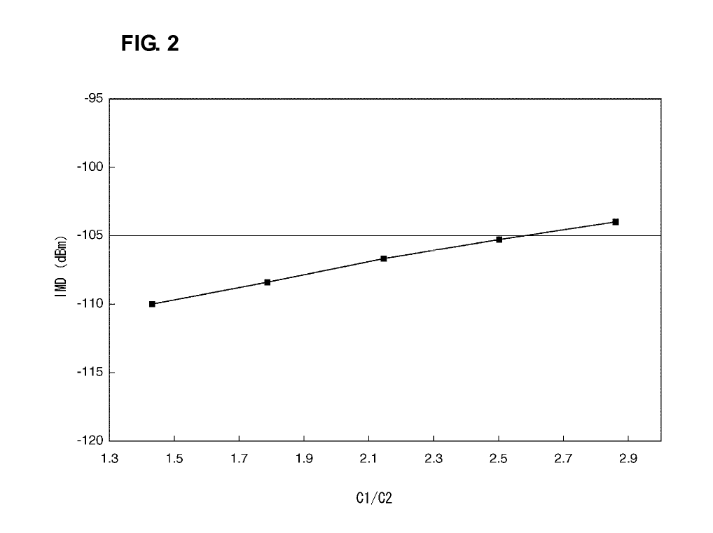

FIG. 2 is a graph showing a relationship between a capacitance ratio C1/C2 and an inter-modulation distortion level. The graph of FIG. 2 was obtained by measuring the inter-modulation distortion level under conditions in which the number of electrode fingers of the IDT electrode 41 of the surface acoustic wave resonator 40 was about 200 and the capacitance ratio C1/C2 was varied by changing the aperture of the IDT electrode 41. Note that the number of electrode fingers of each of the IDT electrodes 31 of the first and second filter portions 30a and 30b was about 34, and the aperture of each of the IDT electrodes 31 was about 40 μm. The surface acoustic wave resonator 40 and the first to fourth filter portions 30a to 30d had the same or substantially the same metallization ratio.

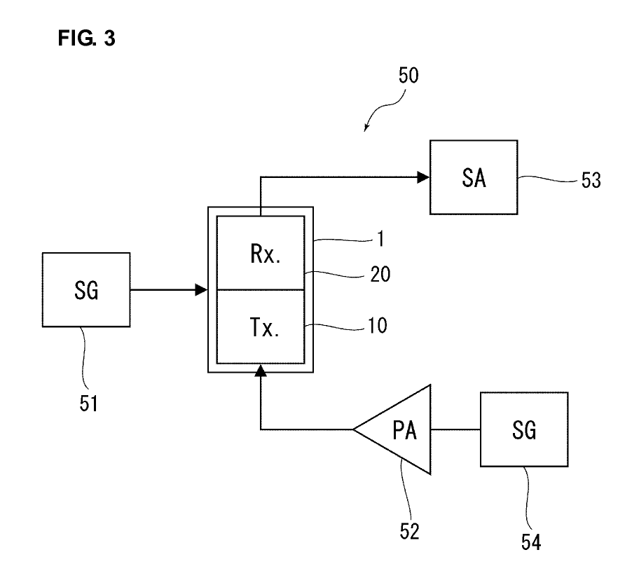

An inter-modulation distortion measurement system 50 schematically illustrated in FIG. 3 was used to measure the inter-modulation distortion. The inter-modulation distortion measurement system 50 includes signal generators 51 and 54, a power amplifier 52, and a spectrum analyzer 53. The duplexer 1 is electrically connected between the signal generator 51, the power amplifier 52, and the spectrum analyzer 53.

First, the inter-modulation distortion measurement system 50 was set such that transmission signals having frequencies of about 1850 MHz and about 1910 MHz generated in the signal generator 54 passed through the power amplifier 52 and the transmission filter 10 and reached about 20 dBm at the antenna terminal Ant. of the duplexer 1.

Next, as interfering waves, the signal generator 51 generated signals having frequencies of (f_{Rx}−f_{Tx}), (f_{Rx}+f_{Tx}), (2f_{Tx}−f_{Rx}), and (2f_{Tx}+f_{Rx}), where f_{Tx} was a transmission frequency and f_{Rx} was a reception frequency. The signal level of the generated signals was about −15 dBm. Then, the inter-modulation distortion level of the generated signals was measured with the spectrum analyzer 53, so that the graph of FIG. 2 was created. Japanese Unexamined Patent Application Publication No. 2007-235303 can be referred to for the details of inter-modulation distortion.

FIG. 2 shows that the inter-modulation distortion level is reduced as the capacitance ratio C1/C2 decreases. This likely occurs because as a difference between the capacitance C1 and the capacitance C2 decreases, a difference between the impedance of the surface acoustic wave resonator 40 and that of each of the IDT electrodes 31 of the first and second filter portions 30a and 30b also decreases and, thus, the impedance of the surface acoustic wave resonator 40 is matched to that of the IDT electrode 31. Generally, the inter-modulation distortion level of a branching filter, such as a duplexer, is required to be about −105 dBm or less, for example. The results of FIG. 2 shows that, to limit the inter-modulation distortion level to about −105 dBm or less, it is necessary to limit the capacitance ratio C1/C2 to about 2.5 or less.

However, if the capacitance of the surface acoustic wave resonator 40 is excessively reduced to reduce the capacitance ratio C1/C2, the quality factor Q of the surface acoustic wave resonator 40 deteriorates. This results in degradation of filter characteristics, such as occurrences of missing high frequencies in the passband of the reception filter 20, deterioration of insertion loss within the passband of the reception filter 20, and reduction of the bandwidth of the reception filter 20. Generally, the bandwidth ratio of a reception filter of a branching filter, such as a duplexer, is preferably about 3.5% or greater, for example. To satisfy this, it is preferable that the capacitance ratio C1/C2 be about 1.9 or greater.

As described above, if the ratio of C1 to C2 (C1/C2) is in the range of, for example, about 1.9 to about 2.5, where C1 is the capacitance of the surface acoustic wave resonator 40 and C2 is, in the first and second filter portions 30a and 30b, the capacitance of each of the IDT electrodes 31 connected to the IDT electrode 41 of the surface acoustic wave resonator 40, it is possible to reduce the inter-modulation distortion level without degrading the filter characteristics of the reception filter 20. Thus, it is possible to improve reception sensitivity of the communication device including the duplexer 1.

Modifications of the above-described preferred embodiment will now be described. In the following description, components having substantially the same functions as those in the above-described preferred embodiment are referred to by the same reference numerals and their description is omitted.

In the preferred embodiment described above, the reception filter 20 preferably has a configuration in which two sets of two longitudinally coupled resonator-type surface acoustic wave filter portions that are cascade-connected to each other are electrically connected in parallel. However, the configuration of the elastic wave branching filter according to preferred embodiments of the present invention is not limited to this. Some exemplary configurations of the reception filter according to modification of a preferred embodiment of the present invention will now be described.

### First Modification

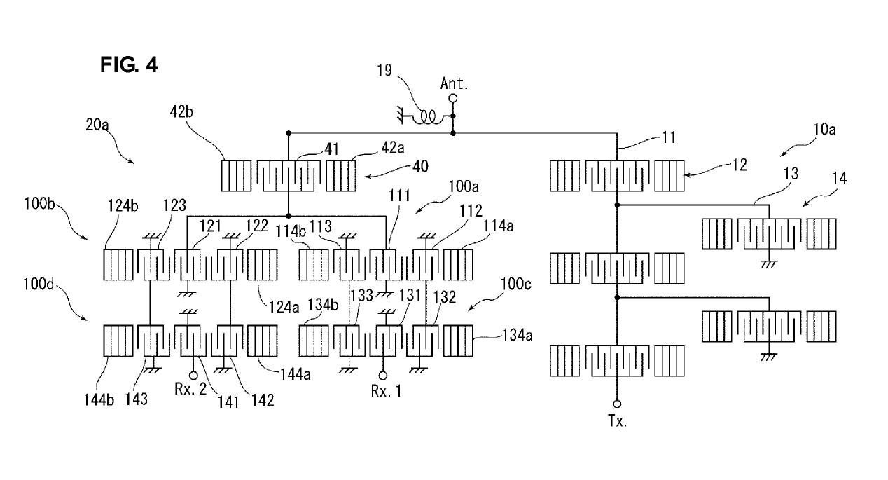

FIG. 4 is a schematic circuit diagram of a duplexer according to a first modification of a preferred embodiment of the present invention. Similar to the duplexer 1 of the preferred embodiment described above, the duplexer of the first modification illustrated in FIG. 4 preferably includes a transmission filter 10a, a reception filter 20a, and a matching circuit including the inductor 19.

The reception filter 20a preferably includes a first longitudinally coupled resonator-type surface acoustic wave filter portion (“first filter portion”) 100a, a second longitudinally coupled resonator-type surface acoustic wave filter portion (“second filter portion”) 100b, a third longitudinally coupled resonator-type surface acoustic wave filter portion (“third filter portion”) 100c, a fourth longitudinally coupled resonator-type surface acoustic wave filter portion (“fourth filter portion”) 100d, and the surface acoustic wave resonator 40. In the duplexer of the first modification, a connection configuration between the reception filter 20a and the first and second reception signal terminals Rx. 1 and Rx. 2 is different from that in the duplexer 1 of the preferred embodiment described above.

The first filter portion 100a preferably includes IDT electrodes 111 to 113 arranged in the surface acoustic wave propagation direction, and reflectors 114a and 114b arranged on both sides in the surface acoustic wave propagation direction of the region in which the IDT electrodes 111 to 113 are arranged. The second filter portion 100b preferably includes IDT electrodes 121 to 123 arranged in the surface acoustic wave propagation direction, and reflectors 124a and 124b arranged on both sides in the surface acoustic wave propagation direction of the region in which the IDT electrodes 121 to 123 are arranged.

The third filter portion 100c is preferably cascade-connected to the first filter portion 100a. The third filter portion 100c preferably includes IDT electrodes 131 to 133 arranged in the surface acoustic wave propagation direction, and reflectors 134a and 134b arranged on both sides in the surface acoustic wave propagation direction of the region in which the IDT electrodes 131 to 133 are arranged.

The fourth filter portion 100d is preferably cascade-connected to the second filter portion 100b. The fourth filter portion 100d preferably includes IDT electrodes 141 to 143 arranged in the surface acoustic wave propagation direction, and reflectors 144a and 144b arranged on both sides in the surface acoustic wave propagation direction of the region in which the IDT electrodes 141 to 143 are arranged.

The first and third filter portions 100a and 100c that are cascade-connected to each other are connected in parallel to the second and fourth filter portions 100b and 100d that are cascade-connected to each other.

The IDT electrode 111 of the first filter portion 100a is connected at one end through the surface acoustic wave resonator 40 to the antenna terminal Ant. and connected at the other end to the ground potential. That is, the IDT electrode 111 of the first filter portion 100a is an IDT electrode connected to the surface acoustic wave resonator 40. The IDT electrode 112 of the first filter portion 100a is connected at one end to the ground potential and connected at the other end to the IDT electrode 132 of the third filter portion 100c. The IDT electrode 113 of the first filter portion 100a is connected at one end to the ground potential and connected at the other end to the IDT electrode 133 of the third filter portion 100c.

The IDT electrode 132 of the third filter portion 100c is connected to the ground potential at an end portion opposite the end connected to the IDT electrode 112 of the first filter portion 100a. Similarly, the IDT electrode 133 of the third filter portion 100c is connected to the ground potential at an end portion opposite the end connected to the IDT electrode 113 of the first filter portion 100a. The IDT electrode 131 of the third filter portion 100c is connected at one end to the ground potential, and connected at the other end to the first reception signal terminal Rx. 1.

The IDT electrode 121 of the second filter portion 100b is connected at one end through the surface acoustic wave resonator 40 to the antenna terminal Ant. and connected at the other end to the ground potential. Specifically, the IDT electrode 121 of the second filter portion 100b and the IDT electrode 111 of the first filter portion 100a are connected at one end in common through the surface acoustic wave resonator 40 to the antenna terminal Ant. That is, the IDT electrode 121 of the second filter portion 100b is an IDT electrode connected to the surface acoustic wave resonator 40. The IDT electrode 122 of the second filter portion 100b is connected at one end to the ground potential and connected at the other end to the IDT electrode 142 of the fourth filter portion 100d. The IDT electrode 123 of the second filter portion 100b is connected at one end to the ground potential and connected at the other end to the IDT electrode 143 of the fourth filter portion 100d.

The IDT electrode 142 of the fourth filter portion 100d is connected to the ground potential at an end portion opposite the end connected to the IDT electrode 122 of the second filter portion 100b. Similarly, the IDT electrode 143 of the fourth filter portion 100d is connected to the ground potential at an end portion opposite the end connected to the IDT electrode 123 of the second filter portion 100b. The IDT electrode 141 of the fourth filter portion 100d is connected at one end to the ground potential and connected at the other end to the second reception signal terminal Rx. 2. The IDT electrode 131 of the third filter portion 100c preferably has a structure obtained by reversing the arrangement of the IDT electrode 141 of the fourth filter portion 100d.

In the first modification, if the ratio of C1 to C2 (C1/C2) is preferably in the range of, for example, about 1.9 to about 2.5, where C1 is the capacitance of the surface acoustic wave resonator 40 and C2 is, in the first and second filter portions 100a and 100b, the capacitance of each of the IDT electrodes 111 and 121 electrically connected to the IDT electrode 41 of the surface acoustic wave resonator 40, it is possible to reduce the inter-modulation distortion level without degrading the filter characteristics of the reception filter 20a.

### Second Modification

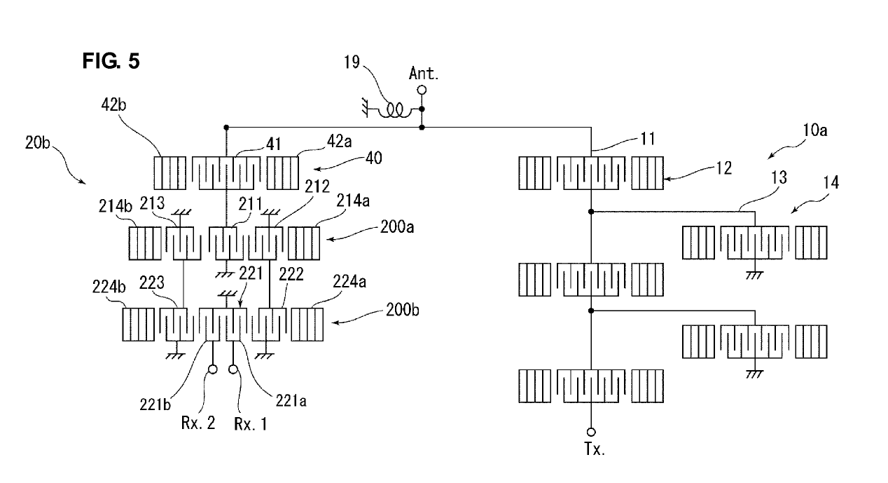

FIG. 5 is a schematic circuit diagram of a duplexer according to a second modification of a preferred embodiment of the present invention. Similar to the duplexer 1 of the preferred embodiment described above, the duplexer of the second modification illustrated in FIG. 5 preferably includes the transmission filter 10a, a reception filter 20b, and a matching circuit defined by the inductor 19.

As illustrated in FIG. 5, in the second modification, the reception filter 20b preferably includes the surface acoustic wave resonator 40, a first longitudinally coupled resonator-type surface acoustic wave filter portion (“first filter portion”) 200a, and a second longitudinally coupled resonator-type surface acoustic wave filter portion (“second filter portion”) 200b. The second filter portion 200b is cascade-connected to the first filter portion 200a.

The first filter portion 200a preferably includes IDT electrodes 211 to 213 arranged in the surface acoustic wave propagation direction, and reflectors 214a and 214b arranged on both sides in the surface acoustic wave propagation direction of the region in which the IDT electrodes 211 to 213 are arranged. The second filter portion 200b preferably includes IDT electrodes 221 to 223 arranged in the surface acoustic wave propagation direction, and reflectors 224a and 224b arranged on both sides in the surface acoustic wave propagation direction of the region in which the IDT electrodes 221 to 223 are arranged. The IDT electrode 221 is preferably divided, in the surface acoustic wave propagation direction, into a first IDT segment 221a and a second IDT segment 221b.

The IDT electrode 211 of the first filter portion 200a is connected at one end through the surface acoustic wave resonator 40 to the antenna terminal Ant. and connected at the other end to the ground potential. That is, the IDT electrode 211 of the first filter portion 200a is an IDT electrode connected to the surface acoustic wave resonator 40. The IDT electrode 212 of the first filter portion 200a is connected at one end to the ground potential and connected at the other end to the IDT electrode 222 of the second filter portion 200b. The IDT electrode 213 of the first filter portion 200a is connected at one end to the ground potential and connected at the other end to the IDT electrode 223 of the second filter portion 200b.

The IDT electrode 222 of the second filter portion 200b is connected to the ground potential at an end portion opposite the end connected to the IDT electrode 212 of the first filter portion 200a. Similarly, the IDT electrode 223 of the second filter portion 200b is connected to the ground potential at an end portion opposite the end connected to the IDT electrode 213 of the first filter portion 200a. In the IDT electrode 221 of the second filter portion 200b, the first IDT segment 221a and the second IDT segment 221b are connected to the first reception signal terminal Rx. 1 and the second reception signal terminal Rx. 2, respectively.

In the second modification, if the ratio of C1 to C2 (C1/C2) is preferably in the range of, for example, about 1.9 to about 2.5, where C1 is the capacitance of the surface acoustic wave resonator 40 and C2 is, in the first filter portion 200a, the capacitance of the IDT electrode 211 electrically connected to the IDT electrode 41 of the surface acoustic wave resonator 40, it is possible to reduce the inter-modulation distortion level without degrading the filter characteristics of the reception filter 20b.

### Third Modification

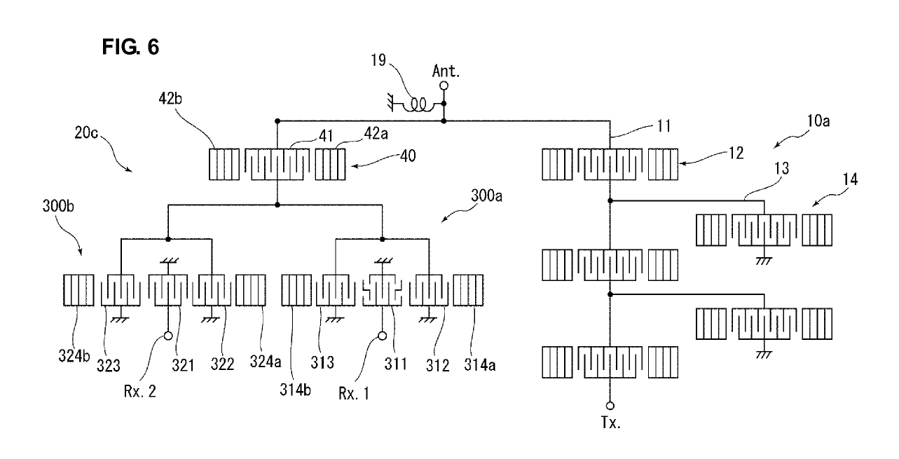

FIG. 6 is a schematic circuit diagram of a duplexer according to a third modification of a preferred embodiment of the present invention. Similar to the duplexer 1 of the preferred embodiment described above, the duplexer of the third modification illustrated in FIG. 6 preferably includes the transmission filter 10a, a reception filter 20c, and a matching circuit defined by the inductor 19.

As illustrated in FIG. 6, in the third modification, the reception filter 20c preferably includes the surface acoustic wave resonator 40, a first longitudinally coupled resonator-type surface acoustic wave filter portion (“first filter portion”) 300a, and a second longitudinally coupled resonator-type surface acoustic wave filter portion (“second filter portion”) 300b. The first filter portion 300a and the second filter portion 300b are connected in parallel.

The first filter portion 300a preferably includes IDT electrodes 311 to 313 arranged in the surface acoustic wave propagation direction, and reflectors 314a and 314b arranged on both sides in the surface acoustic wave propagation direction of the region in which the IDT electrodes 311 to 313 are arranged. The second filter portion 300b preferably includes IDT electrodes 321 to 323 arranged in the surface acoustic wave propagation direction, and reflectors 324a and 324b arranged on both sides in the surface acoustic wave propagation direction of the region in which the IDT electrodes 321 to 323 are arranged.

The IDT electrodes 312 and 313 of the first filter portion 300a are connected at one end in common through the surface acoustic wave resonator 40 to the antenna terminal Ant. and connected at the other end to the ground potential. That is, the IDT electrodes 312 and 313 of the first filter portion 300a are IDT electrodes connected to the surface acoustic wave resonator 40. The IDT electrode 311 of the first filter portion 300a is connected at one end to the ground potential and connected at the other end to the first reception signal terminal Rx. 1.

The IDT electrodes 322 and 323 of the second filter portion 300b are connected at one end in common through the surface acoustic wave resonator 40 to the antenna terminal Ant. and connected at the other end to the ground potential. Specifically, the IDT electrodes 322 and 323 of the second filter portion 300b and the IDT electrodes 312 and 313 of the first filter portion 300a are connected at one end in common through the surface acoustic wave resonator 40 to the antenna terminal Ant. That is, the IDT electrodes 322 and 323 of the second filter portion 300b are also IDT electrodes connected to the surface acoustic wave resonator 40. The IDT electrode 321 of the second filter portion 300b is connected at one end to the ground potential, and connected at the other end to the second reception signal terminal Rx. 2. The IDT electrode 311 of the first filter portion 300a preferably has a structure obtained by reversing that of the IDT electrode 321 of the second filter portion 300b. Series weighting is preferably applied to the IDT electrode 311 of the first filter portion 300a.

In the third modification, if the ratio of C1 to C2 (C1/C2) is preferably in the range of, for example, about 1.9 to about 2.5, where C1 is the capacitance of the surface acoustic wave resonator 40 and C2 is, in the first and second filter portions 300a and 300b, the capacitance of each of the IDT electrodes 312, 313, 322, and 323 electrically connected to the IDT electrode 41 of the surface acoustic wave resonator 40, it is possible to reduce the inter-modulation distortion level without degrading the filter characteristics of the reception filter 20c.

### Fourth Modification

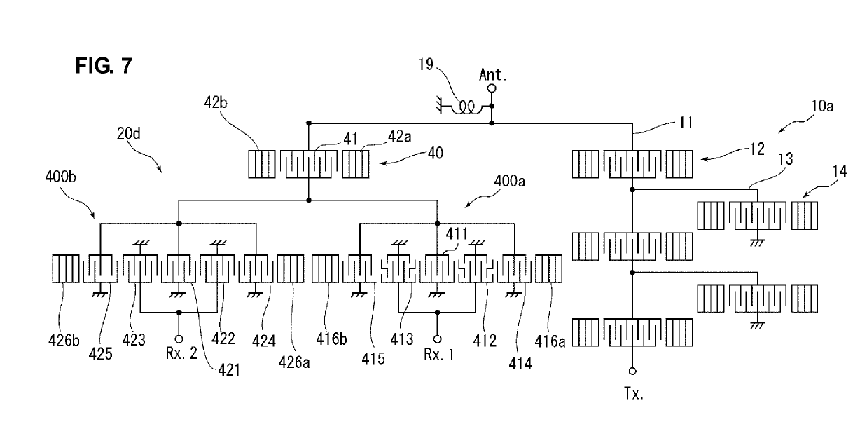

FIG. 7 is a schematic circuit diagram of a duplexer according to a fourth modification of a preferred embodiment of the present invention. Similar to the duplexer 1 of the preferred embodiment described above, the duplexer of the fourth modification illustrated in FIG. 7 preferably includes the transmission filter 10a, a reception filter 20d, and a matching circuit including the inductor 19.

As illustrated in FIG. 7, in the fourth modification, the reception filter 20d preferably includes the surface acoustic wave resonator 40, a first longitudinally coupled resonator-type surface acoustic wave filter portion (“first filter portion”) 400a, and a second longitudinally coupled resonator-type surface acoustic wave filter portion (“second filter portion”) 400b. The first filter portion 400a and the second filter portion 400b are connected in parallel. The duplexer of the fourth modification is different from the duplexer of the third modification, which includes the first and second filter portions 300a and 300b that are three-IDT longitudinally coupled resonator-type surface acoustic wave filters, in that the first and second filter portions 400a and 400b preferably are five-IDT longitudinally coupled resonator-type surface acoustic wave filters.

The first filter portion 400a preferably includes IDT electrodes 411 to 415 arranged in the surface acoustic wave propagation direction, and reflectors 416a and 416b arranged on both sides in the surface acoustic wave propagation direction of the region in which the IDT electrodes 411 to 415 are arranged. The second filter portion 400b preferably includes IDT electrodes 421 to 425 arranged in the surface acoustic wave propagation direction, and reflectors 426a and 426b arranged on both sides in the surface acoustic wave propagation direction of the region in which the IDT electrodes 421 to 425 are arranged.

The IDT electrodes 411, 414, and 415 of the first filter portion 400a are connected at one end in common through the surface acoustic wave resonator 40 to the antenna terminal Ant. and connected at the other end to the ground potential. That is, the IDT electrodes 411, 414, and 415 of the first filter portion 400a are IDT electrodes connected to the surface acoustic wave resonator 40. The IDT electrodes 412 and 413 of the first filter portion 400a are connected at one end to the ground potential and connected at the other end in common to the first reception signal terminal Rx. 1.

The IDT electrodes 421, 424, and 425 of the second filter portion 400b are connected at one end in common through the surface acoustic wave resonator 40 to the antenna terminal Ant. and connected at the other end to the ground potential. Specifically, the IDT electrodes 421, 424, and 425 of the second filter portion 400b and the IDT electrodes 411, 414, and 415 of the first filter portion 400a are connected at one end in common through the surface acoustic wave resonator 40 to the antenna terminal Ant. That is, the IDT electrodes 421, 424, and 425 of the second filter portion 400b are also IDT electrodes connected to the surface acoustic wave resonator 40. The IDT electrodes 422 and 423 of the second filter portion 400b are connected at one end to the ground potential and connected at the other end in common to the second reception signal terminal Rx. 2. The IDT electrodes 412 and 413 of the first filter portion 400a preferably have a structure obtained by reversing that of the IDT electrodes 422 and 423 of the second filter portion 400b. Series weighting is preferably applied to the IDT electrodes 412 and 413 of the first filter portion 400a.

In the fourth modification, if the ratio of C1 to C2 (C1/C2) is preferably in the range of, for example, about 1.9 to about 2.5, where C1 is the capacitance of the surface acoustic wave resonator 40 and C2 is, in the first and second filter portions 400a and 400b, the capacitance of each of the IDT electrodes 411, 414, 415, 421, 424, and 425 electrically connected to the IDT electrode 41 of the surface acoustic wave resonator 40, it is possible to reduce the inter-modulation distortion level without degrading the filter characteristics of the reception filter 20d.

### Fifth Modification

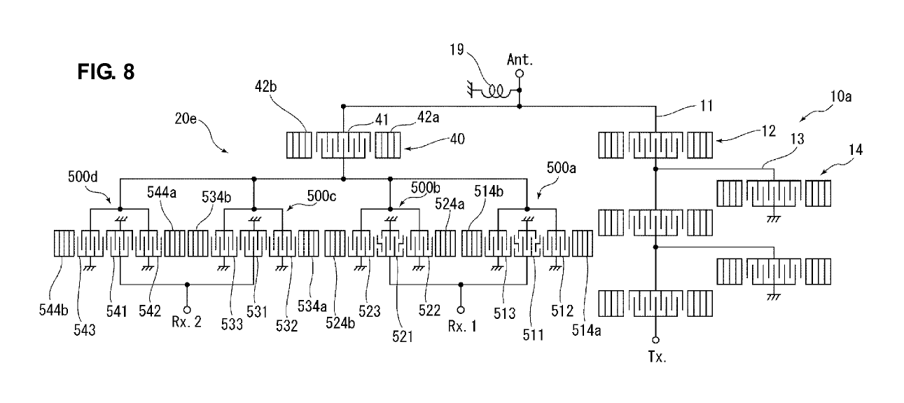

FIG. 8 is a schematic circuit diagram of a duplexer according to a fifth modification of a preferred embodiment of the present invention. Similar to the duplexer 1 of the preferred embodiment described above, the duplexer of the fifth modification illustrated in FIG. 8 preferably includes the transmission filter 10a, a reception filter 20e, and a matching circuit including the inductor 19.

As illustrated in FIG. 8, in the present modification, the reception filter 20e preferably includes the surface acoustic wave resonator 40, a first longitudinally coupled resonator-type surface acoustic wave filter portion (“first filter portion”) 500a, a second longitudinally coupled resonator-type surface acoustic wave filter portion (“second filter portion”) 500b, a third longitudinally coupled resonator-type surface acoustic wave filter portion (“third filter portion”) 500c, and a fourth longitudinally coupled resonator-type surface acoustic wave filter portion (“fourth filter portion”) 500d. The first, second, third, and fourth filter portions 500a, 500b, 500c, and 500d are electrically connected in parallel.

The first filter portion 500a preferably includes IDT electrodes 511 to 513 arranged in the surface acoustic wave propagation direction, and reflectors 514a and 514b arranged on both sides in the surface acoustic wave propagation direction of the region in which the IDT electrodes 511 to 513 are arranged. The second filter portion 500b preferably includes IDT electrodes 521 to 523 arranged in the surface acoustic wave propagation direction, and reflectors 524a and 524b arranged on both sides in the surface acoustic wave propagation direction of the region in which the IDT electrodes 521 to 523 are arranged. The third filter portion 500c preferably includes IDT electrodes 531 to 533 arranged in the surface acoustic wave propagation direction, and reflectors 534a and 534b arranged on both sides in the surface acoustic wave propagation direction of the region in which the IDT electrodes 531 to 533 are arranged. The fourth filter portion 500d preferably includes IDT electrodes 541 to 543 arranged in the surface acoustic wave propagation direction, and reflectors 544a and 544b arranged on both sides in the surface acoustic wave propagation direction of the region in which the IDT electrodes 541 to 543 are arranged.

The IDT electrodes 512 and 513 of the first filter portion 500a are connected at one end in common through the surface acoustic wave resonator 40 to the antenna terminal Ant. and connected at the other end to the ground potential. That is, the IDT electrodes 512 and 513 of the first filter portion 500a are IDT electrodes connected to the surface acoustic wave resonator 40. The IDT electrode 511 of the first filter portion 500a is connected at one end to the ground potential and connected at the other end to the first reception signal terminal Rx. 1.

The IDT electrodes 522 and 523 of the second filter portion 500b are connected at one end in common through the surface acoustic wave resonator 40 to the antenna terminal Ant. and connected at the other end to the ground potential. That is, the IDT electrodes 522 and 523 of the second filter portion 500b are IDT electrodes connected to the surface acoustic wave resonator 40. The IDT electrode 521 of the second filter portion 500b is connected at one end to the ground potential and connected at the other end to the first reception signal terminal Rx. 1. Specifically, the IDT electrode 521 of the second filter portion 500b and the IDT electrode 511 of the first filter portion 500a are connected at one end in common to the first reception signal terminal Rx. 1.

The IDT electrodes 532 and 533 of the third filter portion 500c are connected at one end in common through the surface acoustic wave resonator 40 to the antenna terminal Ant. and connected at the other end to the ground potential. That is, the IDT electrodes 532 and 533 of the third filter portion 500c are IDT electrodes connected to the surface acoustic wave resonator 40. The IDT electrode 531 of the third filter portion 500c is connected at one end to the ground potential and connected at the other end to the second reception signal terminal Rx. 2.

The IDT electrodes 542 and 543 of the fourth filter portion 500d are connected at one end in common through the surface acoustic wave resonator 40 to the antenna terminal Ant. and connected at the other end to the ground potential. That is, the IDT electrodes 542 and 543 of the fourth filter portion 500d are IDT electrodes connected to the surface acoustic wave resonator 40. The IDT electrode 541 of the fourth filter portion 500d is connected at one end to the ground potential and connected at the other end to the second reception signal terminal Rx. 2. Specifically, the IDT electrode 541 of the fourth filter portion 500d and the IDT electrode 531 of the third filter portion 500c are connected at one end in common to the second reception signal terminal Rx. 2. The IDT electrode 511 of the first filter portion 500a and the IDT electrode 521 of the second filter portion 500b preferably have a structure obtained by reversing that of the IDT electrode 531 of the third filter portion 500c and the IDT electrode 541 of the fourth filter portion 500d. Series weighting is preferably applied to the IDT electrode 511 of the first filter portion 500a and the IDT electrode 521 of the second filter portion 500b.

In the fifth modification, if the ratio of C1 to C2 (C1/C2) is preferably in the range of, for example, about 1.9 to about 2.5, where C1 is the capacitance of the surface acoustic wave resonator 40 and C2 is, in the first, second, third, and fourth filter portions 500a, 500b, 500c, and 500d, the capacitance of each of the IDT electrodes 512, 513, 522, 523, 532, 533, 542, and 543 electrically connected to the IDT electrode 41 of the surface acoustic wave resonator 40, it is possible to reduce the inter-modulation distortion level without degrading the filter characteristics of the reception filter 20e.

### Sixth Modification

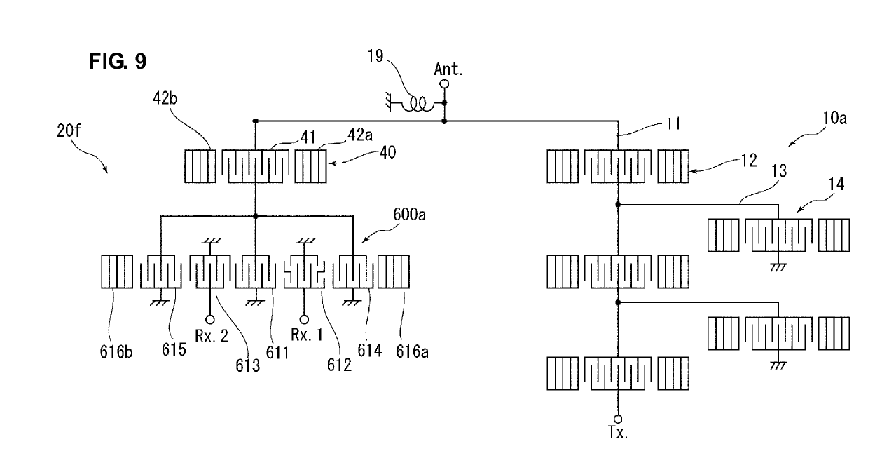

FIG. 9 is a schematic circuit diagram of a duplexer according to a sixth modification of a preferred embodiment of the present invention. Similar to the duplexer 1 of the preferred embodiment described above, the duplexer of the sixth modification illustrated in FIG. 9 preferably includes the transmission filter 10a, a reception filter 20f, and a matching circuit including the inductor 19.

As illustrated in FIG. 9, in the present modification, the reception filter 20f preferably includes the surface acoustic wave resonator 40, a longitudinally coupled resonator-type surface acoustic wave filter portion (“filter portion”) 600a which is a five-IDT longitudinally coupled resonator-type surface acoustic wave filter.

The filter portion 600a preferably includes IDT electrodes 611 to 615 arranged in the surface acoustic wave propagation direction, and reflectors 616a and 616b arranged on both sides in the surface acoustic wave propagation direction of the region in which the IDT electrodes 611 to 615 are arranged.

The IDT electrodes 611, 614, and 615 are connected at one end in common through the surface acoustic wave resonator 40 to the antenna terminal Ant. and connected at the other end to the ground potential. That is, the IDT electrodes 611, 614, and 615 are IDT electrodes connected to the surface acoustic wave resonator 40. The IDT electrodes 612 and 613 are connected at one end to the ground potential and connected at the other end to the first and second reception signal terminals Rx. 1 and Rx. 2, respectively. The IDT electrode 612 preferably has a structure obtained by reversing that of the IDT electrode 613. Series weighting is preferably applied to the IDT electrode 612.

In the sixth modification, if the ratio of C1 to C2 (C1/C2) is preferably in the range of, for example, about 1.9 to about 2.5, where C1 is the capacitance of the surface acoustic wave resonator 40 and C2 is, in the filter portion 600a, the capacitance of each of the IDT electrodes 611, 614, and 615 electrically connected to the IDT electrode 41 of the surface acoustic wave resonator 40, it is possible to reduce the inter-modulation distortion level without degrading the filter characteristics of the reception filter 20f.

### Seventh Modification

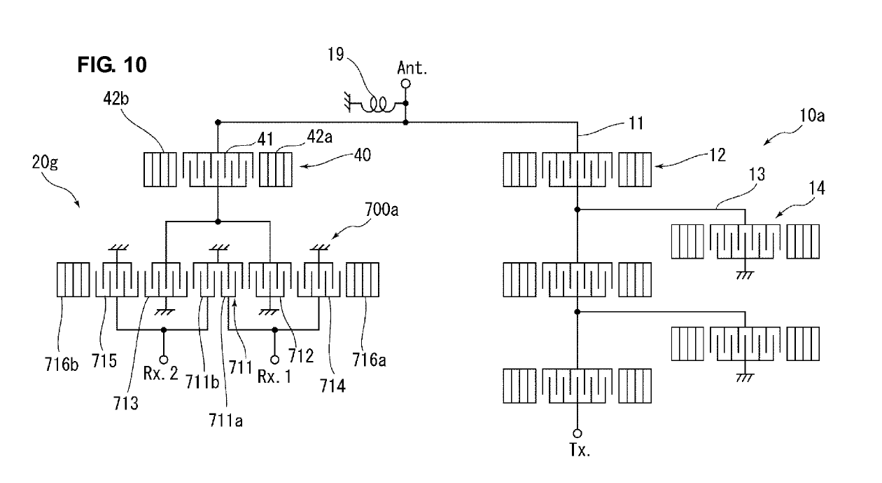

FIG. 10 is a schematic circuit diagram of a duplexer according to a seventh modification of a preferred embodiment of the present invention. Similar to the duplexer 1 of the preferred embodiment described above, the duplexer of the seventh modification illustrated in FIG. 10 preferably includes the transmission filter 10a, a reception filter 20g, and a matching circuit including the inductor 19.

As illustrated in FIG. 10, in the seventh modification, the reception filter 20g preferably includes the surface acoustic wave resonator 40 and a longitudinally coupled resonator-type surface acoustic wave filter portion (“filter portion”) 700a.

The filter portion 700a preferably includes IDT electrodes 711 to 715 arranged in the surface acoustic wave propagation direction, and reflectors 716a and 716b arranged on both sides in the surface acoustic wave propagation direction of the region in which the IDT electrodes 711 to 715 are arranged. The IDT electrode 711 is preferably divided, in the surface acoustic wave propagation direction, into a first IDT segment 711a and a second IDT segment 711b.

The IDT electrodes 712 and 713 are connected at one end in common through the surface acoustic wave resonator 40 to the antenna terminal Ant. and connected at the other end to the ground potential. That is, the IDT electrodes 712 and 713 are IDT electrodes connected to the surface acoustic wave resonator 40. The IDT electrode 712 has a structure obtained by reversing that of the IDT electrode 713. One end of the IDT electrode 714 is connected to the ground potential and the other end of the IDT electrode 714 and the first IDT segment 711a of the IDT electrode 711 are connected in common to the first reception signal terminal Rx. 1. At the same time, one end of the IDT electrode 715 is connected to the ground potential, and the other end of the IDT electrode 715 and the second IDT segment 711b of the IDT electrode 711 are connected in common to the second reception signal terminal Rx. 2.

In the seventh modification, if the ratio of C1 to C2 (C1/C2) is preferably in the range of, for example, about 1.9 to about 2.5, where C1 is the capacitance of the surface acoustic wave resonator 40 and C2 is, in the filter portion 700a, the capacitance of each of the IDT electrodes 712 and 713 electrically connected to the IDT electrode 41 of the surface acoustic wave resonator 40, it is possible to reduce the inter-modulation distortion level without degrading the filter characteristics of the reception filter 20g.

In various preferred embodiments of the present invention, as described above, a capacitance ratio in the reception filter is defined as C1/C2, where C1 is the capacitance of the elastic wave resonator and C2 is, in the longitudinally coupled resonator-type elastic wave filter, the capacitance of the IDT electrode electrically connected to the IDT electrode of the elastic wave resonator. In preferred embodiments of the present invention, the structure of the transmission filter is not limited to a specific one.

In the preferred embodiments and the first to seventh modifications described above, a surface acoustic wave filter using surface acoustic waves is preferably used as a reception filter. Alternatively, a boundary acoustic wave filter using boundary acoustic waves may be used as a reception filter.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An elastic wave branching filter comprising:
an antenna terminal;
a reception signal terminal;
a transmission signal terminal;
a reception filter connected between the antenna terminal and the reception signal terminal; and
a transmission filter connected between the antenna terminal and the transmission signal terminal; wherein
the reception filter includes:
a longitudinally coupled resonator-type elastic wave filter portion connected between the antenna terminal and the reception signal terminal and including at least three IDT electrodes arranged in an elastic wave propagation direction; and
an elastic wave resonator connected between the longitudinally coupled resonator-type elastic wave filter portion and the antenna terminal and including one IDT electrode connected to at least one of the at least three IDT electrodes of the longitudinally coupled resonator-type elastic wave filter portion; and
the reception filter is arranged such that a ratio of C1 to C2 is in a range of about 1.9 to about 2.5, where C1 is a capacitance of the elastic wave resonator and C2 is a capacitance of the at least one of the at least three IDT electrodes of the longitudinally coupled resonator-type elastic wave filter portion.

2. The elastic wave branching filter according to claim 1, wherein the transmission filter is a ladder-type elastic wave filter.

3. The elastic wave branching filter according to claim 1, wherein the reception filter is a balanced longitudinally coupled resonator-type elastic wave filter arranged to perform a balanced-unbalanced transforming function.

4. The elastic wave branching filter according to claim 1, wherein the reception filter is a surface acoustic wave filter using surface acoustic waves.
